(19) United States
(12) Patent Application Publication
(10) Pub. No.: US 2013/0024735 A1
(43) Pub. Date: Jan. 24, 2013

(54) SOLID-STATE MEMORY-BASED STORAGE METHOD AND DEVICE WITH LOW ERROR RATE

(71) Applicants: Hyun Mo Chung, Gyeonggi-do (KR); Franz Michael Schuette, Colorado Springs, CO (US)

(72) Inventors: Hyun Mo Chung, Gyeonggi-do (KR); Franz Michael Schuette, Colorado Springs, CO (US)

(73) Assignee: OCZ TECHNOLOGY GROUP INC., San Jose, CA (US)

(21) Appl. No.: 13/185,689

(22) Filed: Jul. 19, 2011

(51) Int. Cl. H03M 13/05; G06F 11/10; G06F 11/00

(52) U.S. Cl. 714/704; 714/E11.004; 714/E11.034

(57) ABSTRACT

Non-volatile solid-state memory-based storage devices and methods of operating the storage devices to have low initial error rates. The storage devices and methods use bit error rate comparison of duplicate writes to one or more non-volatile memory devices. The data set with a lower bit error rate as determined during verification is maintained, whereas data sets with higher bit error rates are discarded. A threshold of bit error rates can be used to trigger the duplication of data for bit error comparison.

### BACKGROUND OF THE INVENTION

The present invention generally relates to memory devices for use with computers and other processing apparatuses. More particularly, this invention relates to a non-volatile or permanent memory-based mass storage device using flash memory devices or any similar non-volatile memory devices for permanent storage of data.

Mass storage devices such as advanced technology (ATA) or small computer system interface (SCSI) drives are rapidly adopting non-volatile solid-state memory technology such as flash memory (NAND and NOR) or other emerging solid-state memory technology, including phase change memory (PCM), resistive random access memory (RRAM), magnetoresistive random access memory (MRAM), ferromagnetic random access memory (FRAM), organic memories, or nanotechnology-based storage media such as carbon nanofiber/nanotube-based substrates. Currently the most common technology uses NAND flash memory as inexpensive storage memory.

Despite all its advantages with respect to speed and price, flash memory-based mass storage devices have the drawback of limited endurance and data retention caused by the physical properties of the floating gate within each memory cell, the charge of which defines the bit contents of each cell. With the migration to smaller process nodes, write endurance and data retention decrease, which is a drawback that has traditionally been countered by implementing better error correction algorithms. For example, a NAND flash memory device manufactured at 2×nm might have a statistical write endurance of 30 to 50 cycles if no errors are tolerated. However, by using Bose-Chaudhuri-Hocquenghem or low density parity check (LDPC) error correction, the write endurance can be increased to some 3,000 to 5,000 program/erase cycles. Likewise, data retention follows the same trend, smaller process nodes foster higher error rates that can be corrected for the simple reasons that they are expected and that countermeasures are in place. However, despite the planned and accepted marginality of the data, errors can and will occur, especially in data that are subjected to read and write disturbance or that are not accessed frequently enough to monitor increases in error rates due to leakage currents causing creeping discharge of the floating gates.

As discussed above, integrity of data stored in NAND flash does not improve over time, but instead deteriorates over time for a number of reasons including environmental factors. By extension, data having an elevated error rate from the beginning are at higher risk for corruption beyond recovery (the uncorrectable bit error rate, or UBER, of the data) than data that start with a very low error rate. It is, therefore, desirable to keep error rates, especially in mission-critical environments at the lowest possible rate.

### BRIEF DESCRIPTION OF THE INVENTION

The present invention provides non-volatile solid-state memory-based storage devices and methods of operating the storage devices to have low initial error rates.

According to a first aspect of the invention, one such method comprises receiving data from a host system, writing a first copy of the data to a first address in the memory devices of a non-volatile solid-state memory-based storage device, optionally encoding the data for error checking and correction by the storage device, checking a bit error rate of the first copy of the data written to the memory devices, and writing a second copy of the data to a second address in the memory devices if the bit error rate of the first copy exceeds a threshold. According to a preferred aspect of the invention, the threshold is lower than or equal to an uncorrectable bit error rate (UBER) threshold at which the data would be lost due to corruption. According to another preferred aspect of the invention, the first or second copy having a higher bit error rate is discarded. The discarded copy may be added to a pool destined for garbage collection and/or erasing, for example through a TRIM command, whereas the copy with the lower bit error rate becomes the final version of the data in the storage device.

According to a second aspect of the invention, a solid-state drive is provided that includes a controller, a cache memory, and one or more non-volatile memory devices. The controller includes an error checking and correction (ECC) engine operable to encode data written from a host system to the storage device. Data written to the memory devices are checked for bit error rates. According to particular aspects of the invention, a set of data written to a memory device simultaneously occurs with the writing of a copy of the data to another address of the memory devices. Alternatively, the copy of the data can be written to the other address if the bit error rate of the set of data is within a range acceptable for error correction but exceeds a threshold. Another alternative is to write first and second copies of the data to first and second addresses of the memory devices if an average of the bit error rate of data written to the memory devices increases beyond a threshold. The bit error rates of the data and its copy can then be compared the data or its copy having the higher bit error rate can be discarded.

According to preferred aspects of the invention, all data writes are carried out in duplicate and valid sets of data is selected on the basis of having lower initial error rates by linking the data to a pointer.

Other aspects and advantages of this invention will be better appreciated from the following detailed description.

### BRIEF DESCRIPTION OF THE DRAWINGS

FIG. 1 shows a flow diagram for a preferred embodiment of the invention, wherein data are written to two physical addresses, the bit error rates (BER) are established for both instances, compared with each other, and the instance with the lower BER is linked to a pointer whereas the instance with the higher BER is discarded by invalidating the entry.

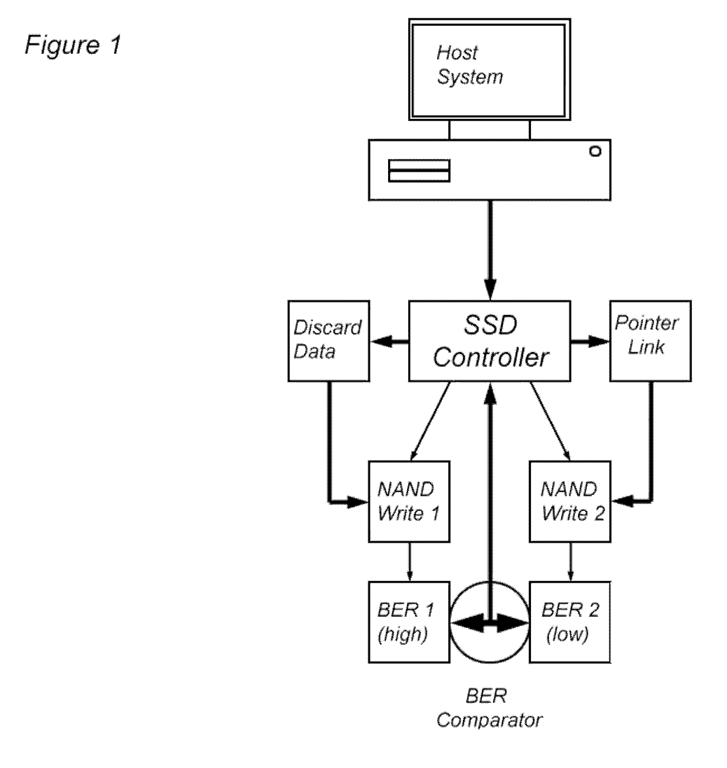

### DETAILED DESCRIPTION OF THE INVENTION

The present invention is generally applicable to computers and other processing apparatuses, and particularly to computers and apparatuses that utilize nonvolatile (permanent) memory-based mass storage devices, a notable example of which are solid-state drives (SSDs) that make use of NAND flash memory devices. A non-limiting example is an internal mass storage device for a computer or other host system equipped with a data and control bus for interfacing with an SSD. The bus may operate with any suitable protocol in the art, preferred examples being the advanced technology attachment (ATA) bus in its parallel or serial iterations, fiber channel (FC), small computer system interface (SCSI), and serially attached SCSI (SAS).

As known in the art, SSDs are adapted to be accessed by a host system with which it is interfaced. Access is initiated by the host system for the purpose of storing (writing) data to and retrieving (reading) data from an array of solid-state nonvolatile memory devices, each being an integrated circuit (IC) chip carried on a circuit board. According to a first aspect of the invention, the memory devices are NAND flash memory devices that are written to and read from over a parallel, combined command and data bus. As known in the art, NAND flash devices are generally written to and read from in pages or fractions thereof and erased in blocks. Alternatively, the memory devices could be NOR flash, phase change memory (PCM), magnetoresistive memory (MRAM), and/or resistive memory (RRAM) devices.

Existing SSDs receive data to be stored from the host system via a host bus controller. The data are subsequently queued up inside a buffer on an internal controller of the SSD, encoded for error checking and correction (ECC) using any suitable ECC implementation (protocol) known in the art, for example, a Reed-Solomon (RS), Bose-Ray-Chaudhuri-Hocquenghem (BCH) or low density parity check (LDPC) algorithm, and then distributed over several channels to be written to the memory devices after physical addresses have been generated by an address (flash) translation layer. With increasing error rates and more sophisticated error correction schemes, a drastic shift in the computational load has occurred, in that the actual correction of errors now occupies the majority of resources. In addition, as more errors occur, a heavier load is placed on the controller and the time that is spent correcting errors.

Aside from being non-perfect media with respect to error rates, NAND flash memory devices also face the drawback of a limitation in program/erase (P/E) cycles. Specifically, each cell inherently has a maximum number of P/E cycles before its oxide layer degrades to the point where programming and erasing becomes either unreliable or too slow to comply with the tolerances of the device. The limited write endurance of NAND flash memory devices is relative to the present invention, as discussed below. With a correct implementation, the benefits of the invention with respect to maintaining low initial error rates and concomitant low error correction workload should outweigh the drawbacks with respect to increasing write load.

In preferred embodiments of the invention, data to be written to one or more memory devices of an SSD are duplicated after encoding them for error correction using a suitable ECC implementation, and then written to two separate physical locations using two distinct channels. The simultaneous write actions require writing to different memory devices in order to avoid bus contention. Through verification of the data after writing, the bit error rate (BER) for both sets of written data is determined. Since there is no need for correcting the data at this point, the load on the controller is minimal. Moreover, encoding of the data for ECC only needs to be done once since both data sets written to the memory devices are identical. For a valuation of the BER, additional factors like clustering of errors can be factored in for the purpose of biasing the BER for an “effective BER.” The BERs of both sets of data are then compared with each other, and the data set with the lower error rate is linked to the pointer validating the data. The set of data with the higher error rate can be invalidated and erased by applying garbage collection and TRIM functions.

According to a particular aspect of the invention, a threshold for a tolerable initial bit error rate can be determined, for example, set at a level that is lower than or equal to an uncorrectable bit error rate (UBER) threshold, which as known in the art refers to the number of errors above which the data can no longer be reconstructed with the ECC implementation used and, as a result, are irrevocably lost or corrupted. As a particular example, the threshold could be set as one-half of the maximum correctable bit error rate of the ECC implementation used. Furthermore, the threshold can be biased by patterns of errors in the data written to the memory devices. With the establishment of a suitable threshold, data are written to two locations on the memory devices only in the event that the BER of the data exceeds the predetermined threshold. In other words, in addition to being written to a first location of the memory devices, the data are duplicated and also written to a second location and, if necessary, to a third location on the memory devices. The patterns of the data written, and the history of the particular page they are committed to, may influence the initial quality of the data in this case. Once a BER has been reached that is below the threshold, the data set becomes the final instance. Alternatively, a rule can be instated, limiting the number of duplications in order to avoid excessive bloating of the write amplification.

In a further aspect of the invention, the storage device operates initially in a standard mode, that is, without any duplication of data. If bit error rates globally increase (for example, an average of the BERs) as a factor of, for example, the age of the device or environmental conditions, the device can switch to a parallel write mode in which the same data are written to different locations and their BERs compared to determine which set of data has the lowest BER. The data set with the lower BER is retained, and the data set with the higher BER can be discarded. If the global BER drops below a certain threshold, for example as a function of changed environmental conditions, the drive will resume normal operation in single write mode. This mode of operation can be particularly useful in situations of harsh environmental conditions where the device is exposed to either extreme heat or cold.

An additional aspect of the invention uses a method for comparing bit error rates to determine the highest initial data integrity of a data set written to memory devices of a solid-state drive. The data set with the higher bit error rate is discarded and the block to which it was written can be subjected to garbage collection and TRIM, whereas the data with the lower BER are linked to the pointer. In addition, bit error rates of blocks can be logged, from which an average bit error rate for each block can be calculated. If a given block repeatedly shows a high initial bit error rate as evidenced by its average bit error rate exceeding a threshold, the block can be flagged as compromised and then subsequently erased and suspended from use by the drive, such as by adding the block to a pool of reserve blocks that is excluded from program/erase (P/E) cycles for a predetermined amount of average P/E cycles as measured by a wear-leveling indicator, during which time and temperature-induced self-healing of the memory devices is allowed to occur. The block can remain in the pool of reserve blocks until the average wear count of all blocks has increased an incremental number of cycles, which can be logged as terabytes written to the drive divided by the drive's capacity. Once the number of cycles has been completed, the block can be re-instituted to the pool of usable blocks. In order to be efficient, a temporary suspension will need to be matched to the usage pattern and history of the device. Accordingly, a suspension of blocks could entail that the incremental number of cycles of the average wear count is a percentage of P/E cycles logged for the block. In case that higher than average error rates persist after lifting a temporary suspension of the block, the block can be flagged as bad by bad block management.

While certain components are shown and preferred for the high data integrity storage device of this invention, it is foreseeable that functionally-equivalent components could be used or subsequently developed to perform the intended functions of the disclosed components. Therefore, while the invention has been described in terms of a preferred embodiment, it is apparent that other forms could be adopted by one skilled in the art, and the scope of the invention is to be limited only by the following claims.

1. A method for increasing the data integrity of a non-volatile solid-state memory-based storage device comprising one or more non-volatile memory devices, the method comprising:
receiving data from a host system;
writing a first copy of the data to a first address in the memory devices of the storage device;
checking a bit error rate of the first copy of the data written to the memory devices using an error checking and correction (ECC) implementation; and
writing a second copy of the data to a second address in the memory devices if the bit error rate of the first copy exceeds a threshold, the threshold being lower than or equal to an uncorrectable bit error rate threshold of the data associated with the ECC implementation.

2. The method of claim 1, wherein the memory devices are chosen from the group comprising NAND flash, NOR flash, phase change memory, magnetoresistive memory, and resistive memory.

3. The method of claim 1 wherein, if the bit error rate of the first copy and a bit error rate of the second copy are above the threshold, the data are written to a third location in the memory devices.

4. The method of claims 1, wherein the threshold is one-half of a maximum correctable bit error rate of the data using the ECC implementation.

5. The method of claim 1, wherein the threshold is biased by patterns of errors in the first and second copies of the data.

6. A method for increasing the data integrity of a non-volatile solid-state memory-based storage device comprising one or more non-volatile memory devices, the method comprising:
receiving data from a host system;
encoding the data with the storage device for error checking and correction using an error checking and correction (ECC) implementation;
writing a first copy of the data to a first address in the memory devices;
checking a bit error rate of the first copy of the data written to the memory devices; and
writing a second copy of the data to a second address in the memory devices if the bit error rate of the first copy exceeds a threshold, the threshold not exceeding an uncorrectable bit error rate threshold of the data associated with the ECC implementation.

7. The method of claim 6, wherein the non-volatile solid-state memory devices are chosen from the group comprising NAND flash, NOR flash, phase change memory, magnetoresistive memory, and resistive memory.

8. The method of claim 6 wherein, if the bit error rate of the first copy and a bit error rate of the second copy are above the threshold, the data are written to a third location in the memory devices.

9. The method of claims 6, wherein the threshold of the bit error rate is one-half of a maximum correctable bit error rate of the data using the ECC implementation.

10. The method of claim 8, wherein the threshold is biased by patterns of errors in the first and second copies of the data.

11. A method for increasing the data integrity of a non-volatile solid-state memory-based storage device comprising one or more non-volatile memory devices, the method comprising:
receiving data from a host system;
encoding the data with the storage device for error checking and correction using an error checking and correction (ECC) implementation;
writing a first copy and a second copy of the data to a first address and a second address, respectively, in the memory devices;
checking the bit error rates of the first and second copies of the data written to the memory devices; and
discarding either of the first and second copies having a higher bit error rate.

12. The method of claim 11, further comprising:
logging of bit error rates of blocks of the memory devices;
calculating an average bit error rate for each block; and
if the average bit error rate of a block exceeds a threshold, erasing the block and suspending the block from use by the storage device until the average wear count of all blocks has increased an incremental number of cycles.

13. The method of claim 12 where the incremental number of cycles of the average wear count is a percentage of program/erase cycles logged for the block.

14. The method of claim 11, wherein the memory devices are chosen from the group comprising NAND flash, NOR flash, phase change memory, magnetoresistive memory, and resistive memory.

15. A mass storage device comprising a host system interface and a printed circuit board having a controller and one or more solid-state non-volatile memory devices mounted thereon, the memory devices being addressable individually over discrete channels of the controller, the controller comprising:
an error checking and correction (ECC) engine operable to encode data written from a host system to the storage device according to an ECC algorithm and to determine bit error rates of data written to the memory devices;
means for writing a set of the data to a first address of the memory devices and, if the bit error rate of the set of data is within a range acceptable for error correction but exceeds a threshold, writing a copy of the set of the data to a second address of the memory devices; and
means for comparing the bit error rate of the copy of the set of the data written to the second address to the bit error rate of the set of the data written to the first address and discarding the set of the data or the copy thereof having a higher bit error rate.

16. The mass storage device of claim 15, wherein the memory devices are chosen from the group comprising NAND flash, NOR flash, phase change memory, magnetoresistive memory, and resistive memory.

17. A solid-state mass storage device comprising a controller, a cache memory, and one or more non-volatile memory devices, the memory devices each being connected to an independent channel of the controller, the controller comprising:
an error checking and correction (ECC) engine for ECC-encoding data written from a host system to the storage device before writing the ECC-encoded data to one of the memory devices;
means for monitoring a bit error rate of the ECC-encoded data written to the memory devices;
means for writing a first copy of the ECC-encoded data to a first address of the memory devices and, in parallel, writing a second copy of the ECC-encoded data to a second address of the memory devices; and
means for monitoring the bit error rates of the first and second copies of the ECC-encoded data and discarding either of the first and second copies having a higher bit error rate.

18. The method of claim 17, wherein the memory devices are chosen from the group comprising NAND flash, NOR flash, phase change memory, magnetoresistive memory, and resistive memory.

19. A solid-state mass storage device comprising a controller, a cache memory, and one or more non-volatile memory devices, the memory devices each being connected to an independent channel of the controller, the controller comprising:
an error checking and correction (ECC) engine for ECC-encoding data written from a host system to the storage device before writing the ECC-encoded data to the memory devices;
means for monitoring a bit error rate of the ECC-encoded data written to the memory devices and, if an average of the bit error rate of the ECC-encoded data increases beyond a threshold, switching to a parallel mode by writing a first copy of the ECC-encoded data to a first address of the memory devices and substantially simultaneously writing a second copy of the ECC-encoded data to a second address of the memory devices; and
means for monitoring the bit error rates of the first and second copies of the ECC-encoded data and discarding either of the first and second copies having a higher bit error rate.

20. The method of claim 19, wherein the non-volatile solid-state memory devices are chosen from the group comprising NAND flash, NOR flash, phase change memory, magnetoresistive memory, and resistive memory.
